(19) United States
(12) Patent Application Publication
(10) Pub. No.: US 2004/0049901 A1
(43) Pub. Date: Mar. 18, 2004

(54) Method for making a multielement acoustic probe using a metallised and ablated polymer as ground plane

(76) Inventor: Ngoc Tuan Nguyen, Mougins (FR)

Correspondence Address: LOWE HAUPTMAN GILMAN & BERNER, LLP, 1700 DIAGNOSTIC ROAD, SUITE 300, ALEXANDRIA, VA, 22314, US

(21) Appl. No.: 10/450,813

(22) PCT Filed: Dec. 11, 2001
(86) PCT No.: PCT/FR01/03931

(30) Foreign Application Priority Data
Dec. 19, 2000 (FR) 00/16594

(51) Int. Cl. H04R 17/00; H05K 3/02

(52) U.S. Cl. 29/25.35; 29/594; 29/846

(57) ABSTRACT

The invention concerns a method to manufacture acoustic probes comprising unitary piezoelectric transducers. The method comprises an original step to realize an earth plane formed from a flexible dielectric film covered by a conducting film. The flexible dielectric film is ablated locally to expose the conducting film. The ablated film acts as draping and earth plane for the unitary piezoelectric transducers.

The invention concerns the field of acoustic probes in particular used for medical imaging and more precisely the field of probes composed of several elements (or channels) excited independently from each other.

Methods of realizing these probes have been described in several documents and in particular in the patent application WO 97/17145. This method consists of first realizing an assembly: printed circuit comprising an interconnection network/layer of piezoelectric material/acoustic matching blades. More precisely, the printed circuit comprises conducting tracks used to contact various acoustic elements. The earth electrode is common to all the elements and is realized by inserting between the acoustic matching blades and the layer of piezoelectric material, a thin metallic or metallized polymer film.

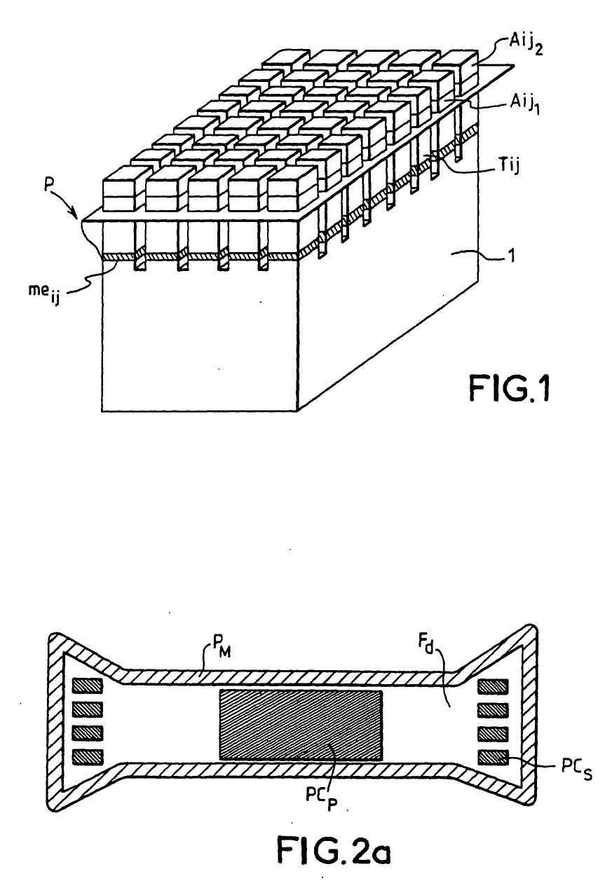

This thin film is then folded over on the sides as illustrated on FIG. 1 which shows the transducer elements Tᵢⱼ (made from piezoelectric material), and acoustic matching elements Aⱼ₁ and Aⱼ₂ whose impedance varies in order to ensure efficient acoustic matching. Each elementary transducer can therefore be controlled between the earth plane P and a metallization Meᵢⱼ connected to the interconnection network 1. To satisfy size restrictions the flexible earth plane is folded over on the sides of the probe, leading due to the radius of curvature of said plane to a dimension generally around 500 μm, thereby increasing the footprint of the probe.

In addition, note that this earth plane located between the piezoelectric elements and the acoustic matching elements causes disturbance in the propagation of the sound waves resulting in loss of acoustic performance of the probe.

The increased size of the probe footprint and/or loss of acoustic performance represent limiting factors for endocardial or cardiological applications which use probes of small footprint and high acoustic performance.

In this context, this invention proposes a new method to manufacture acoustic probes using an original method to manufacture the earth plane.

More precisely, the invention concerns a method to manufacture acoustic probes with unitary piezoelectric transducers, wherein it comprises the following steps:

realization of a connection network comprising primary connections and earth pads, on the surface of a dielectric film;

superposition of a layer of piezoelectric material on the surface of the connection network;

realization of a conducting film on the surface of a flexible film;

ablation over a specific area of the flexible film, exposing the conducting film over the area where the flexible film has been removed;

assembly of the bared conducting film, on the surface of the piezoelectric material and of the flexible film on the surface of the dielectric film;

an operation along a first axis to cut the assembly consisting of the conducting film and the piezoelectric material so as to define the unitary piezoelectric transducers.

Advantageously, the flexible film is a Polyimide film and the conducting film is a metallic film.

Advantageously, the metallic film can be realized in two steps. A first metallization is realized on the surface of the flexible film, then a second metallization is carried out to increase the metallization thickness.

According to a variant of the invention, the flexible film may have a thickness of approximately 10 to 25 μm and the dielectric film may have a thickness of approximately 25 to 50 μm.

According to a variant of the invention, the first metallization step is carried out by spraying or by an electroless process (the electroless process or the metallization using a chemical method consists of dipping the film in a bath saturated in ions of the metal to be deposited. The saturation produces a metallic deposit on the surface of the film). The second step can be realized by electrolytic deposit. During the first metallization step, a thickness of the order of one micron can generally be obtained, whereas the second step produces a thickness which can reach a dozen or so microns.

According to a variant of the invention, the flexible film can be ablated locally by a CO₂ type laser to remove the flexible film locally, leaving only the metallic layer.

Advantageously, the metallic film can be made from copper or nickel.

The method according to the invention may also comprise a third metallization step, with a noble metal, for example gold, to prevent oxidation of the metallic film obtained in the previous steps.

According to a variant of the invention, the assembly of the flexible film on the surface of the dielectric film may also be realized by using an adhesive of type liquid adhesive polymerizable at ambient temperature or when hot.

According to another variant of the invention, the method may comprise the deposit of an intermediate adhesive conducting layer between the piezoelectric material and the dielectric film.

Using the method of the invention, the localized ablation of the flexible film leaves the conducting film only, over a particular area of contact with the layer of piezoelectric material.

Since the conducting film is very thin, there is no significant change in the acoustic properties of the probe. In addition, this thin metallic film is easy to handle since it is supported around the outside by the flexible film.

The invention will be clearer and other advantages will appear on reading the following description given as a non-limiting example, with reference to the attached figures in which:

FIG. 1 illustrates a configuration of acoustic probe according to the known state of the art, comprising an earth plate between the piezoelectric transducers and the matching blades;

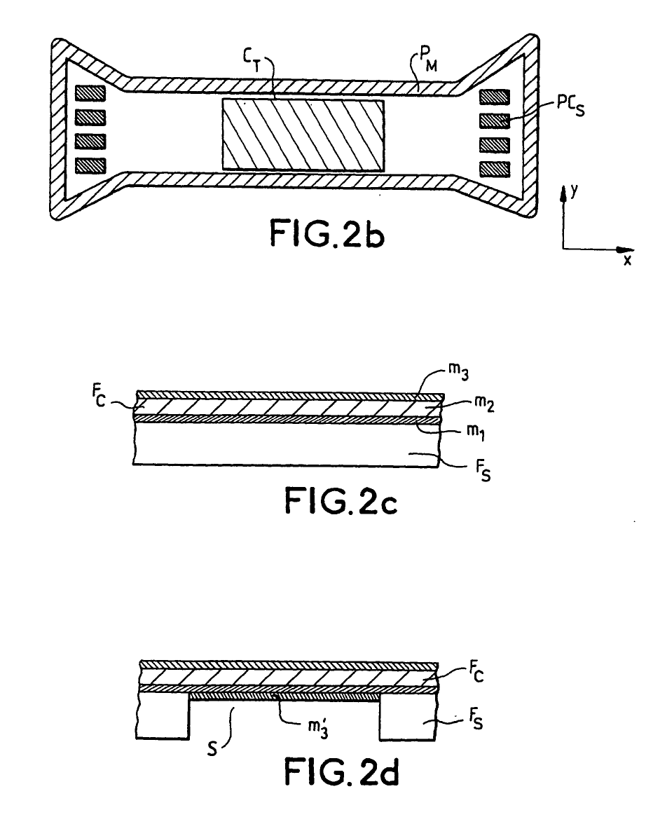

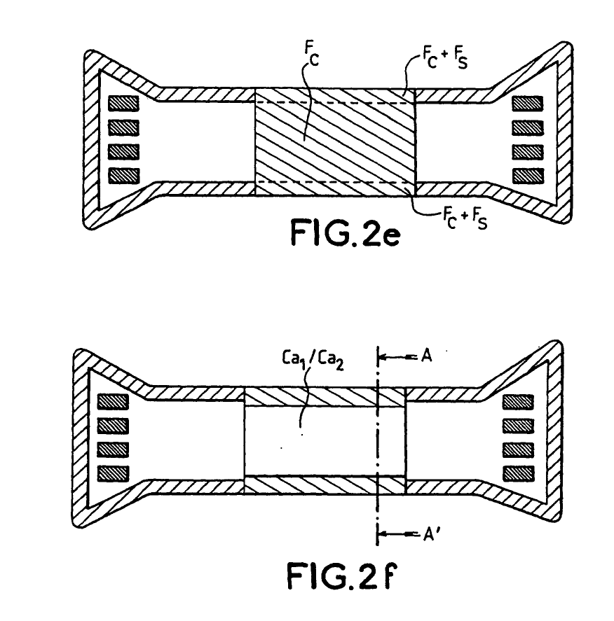

FIGS. 2a to 2f illustrate the main steps of the method according to the invention;

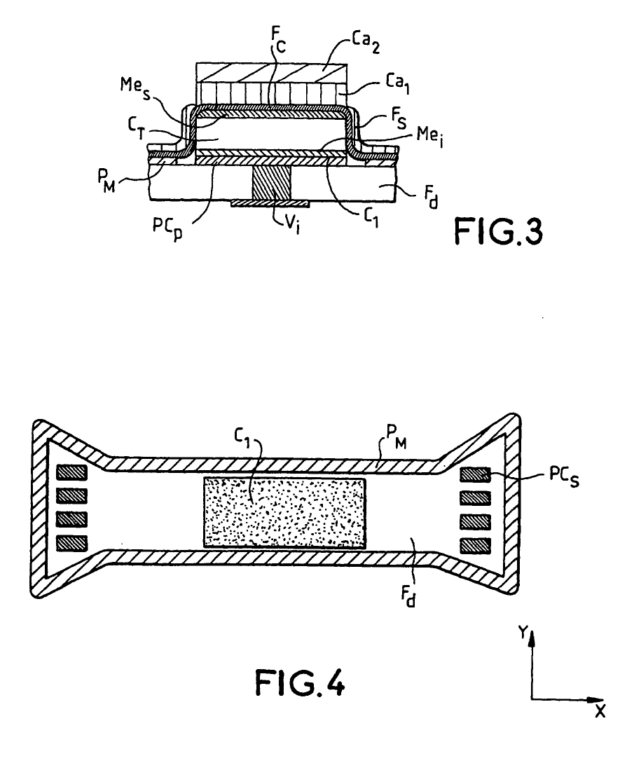

FIG. 3 illustrates a cross-section of a probe manufactured according to the method described in FIGS. 2a to 2f;

FIG. 4 illustrates a step in the method according to the invention comprising the deposit of an intermediate conducting layer between the piezoelectric material and the dielectric film;

FIG. 5 illustrates a cross-section of a probe manufactured using an intermediate conducting layer;

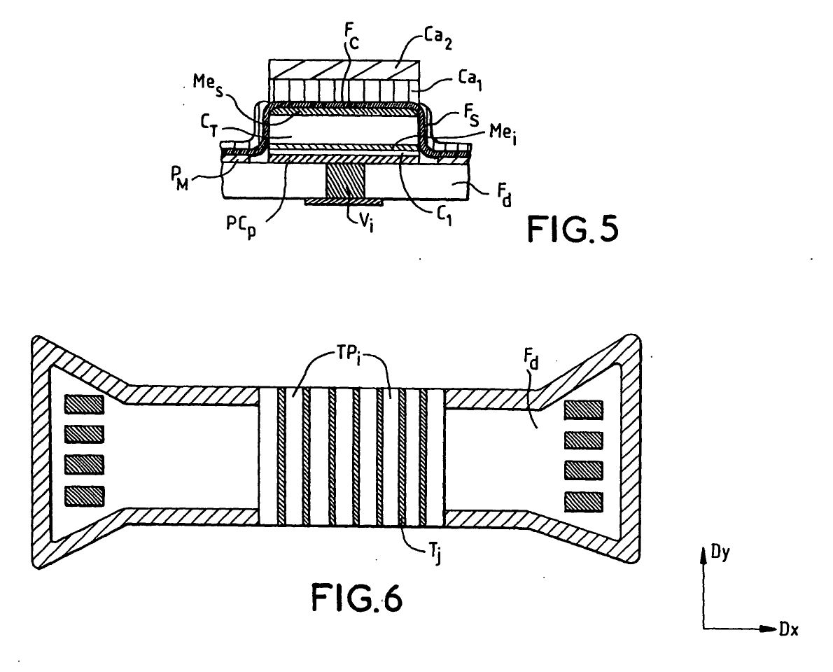

FIG. 6 illustrates a cutting step in order to obtain unitary transducers, included in the method of the invention;

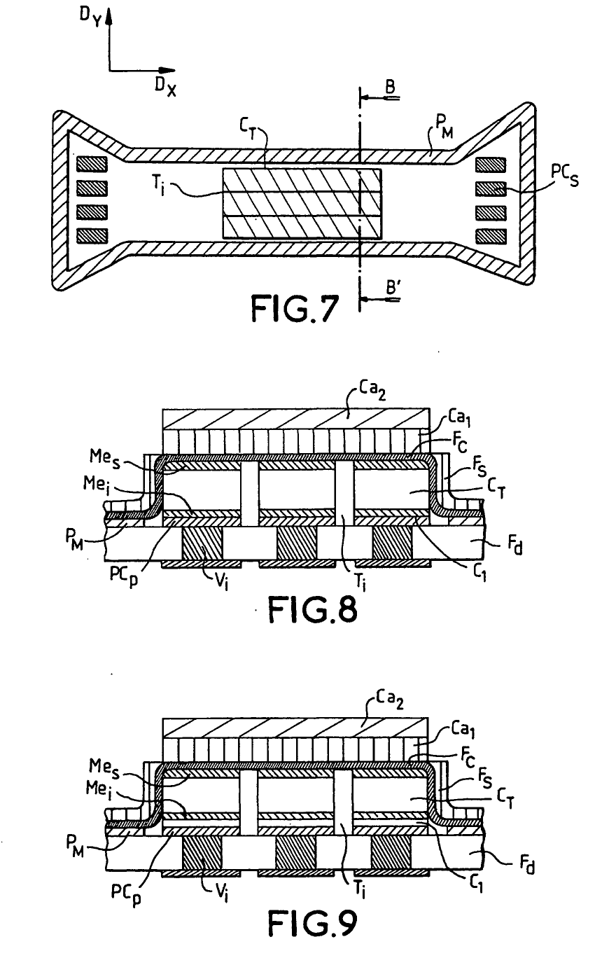

FIG. 7 illustrates a piezoelectric transducer cutting step in a second example of probe manufacturing method according to the invention;

FIG. 8 illustrates a cross-section of a probe manufactured according to the second example illustrated on FIG. 7;

FIG. 9 illustrates a cross-section of a probe manufactured according to FIG. 7 and comprising in addition an intermediate conducting layer.

We will now describe an example of a unidirectional acoustic probe comprising linear piezoelectric transducers, realized according to the method of the invention.

Generally, the probe comprises a set of unitary piezoelectric transducers, each comprising an earth electrode and a control electrode also called “hot point”, in the field of ultrasound sensors.

Advantageously, to connect these electrodes, a flexible dielectric film is used, on which connections for the hot points and the earth electrodes are realized. FIG. 2a illustrates this type of printed circuit.

More precisely, the dielectric film Fd comprises primary connection pads Pcₚ which will be opposite the piezoelectric transducers, secondary connection pads Pcₛ offset with respect to the transducers and earth pads P_{M} which will make contact with the earth electrodes.

More precisely, the primary connection pads and the secondary connection pads are connected via conductors and conducting pads realized on the side of the flexible dielectric film opposite that where the piezoelectric transducers are connected. With this type of configuration, contact can be made with all the transducer electrodes from the same side.

We will describe below the steps required to realize an acoustic probe according to the invention.

According to the method of the invention, on the primary connection pads Pcₚ (FIG. 2a) intended for electrical and mechanical connections a layer of piezoelectric material intended for the manufacture of piezoelectric transducers is deposited (FIG. 2b).

Note that the layer C_{T} does not cover the earth pads PM and the secondary connection pads Pcₛ which must be accessible from the side shown on FIG. 2b. The layer of piezoelectric material is metallized on both sides.

Simultaneously, a conducting film is realized on the surface of a flexible film.

The flexible film may be a polyimide type film of thickness between approximately 10 and 25 μm and metallized on one side as illustrated on FIG. 2c. A first metallization m₁ can be produced by spraying or electroless process on the flexible film Fₛ. Typically, this metallization m₁ is less than about 1 μm thick.

A second metallization m₂ may then be carried out on the surface of the metallization m₁ by electrolytic deposit of the same metal to reach a thickness of between approximately 5 and 10 μm.

Advantageously, a very thin layer approximately 0.3 μm thick of noble metal which does not oxidize can be flashed (metallization m₃) on the surface of the second metallization m₂.

The metallizations m₁/m₂/m₃ therefore form the conducting film F_{c}, of thickness approximately 5 to 10 μm.

In a second step illustrated in FIG. 2d, the flexible film Fₛ is locally engraved by CO₂ laser for example, to expose over the area S, the conducting film F_{c}. Advantageously, another flash of gold can be applied over the area S forming the metallization m′₃.

The draping can be carried out by pressing under pressure at ambient temperature or at high temperature.

A hot polymerizable liquid adhesive is used to bond the assembly (piezoelectric layer/film F_{c} interface and film Fₛ/film Fd interface).

FIG. 3 illustrates a cross-section along axis AA′ represented in FIG. 2f.

When the layer C_{T} of piezoelectric material metallized on the top and bottom sides is positioned on the primary connection pads Pcₚ, the film Fₛ covered by the film F_{c}, intended to drape the entire ceramic layer is positioned on the dielectric film Fd. To do this, the area of the ablated film Fₛ is greater than that of the piezoelectric material in order to obtain efficient draping, going down onto the dielectric film (FIG. 2e).

More precisely, FIG. 3 shows the electrical contact between the lower metallization Meᵢ of the ceramic and the primary connection pad, and the electrical contact formed between the upper metallization Meₛ of the ceramic layer and the earth pad P_{M} by the conducting film F_{c} supported by the film Fₛ. The electrical contacts between the various layers are formed by the roughness of the surfaces. On FIG. 3, the very thin layer of adhesive (less than one micron) is not shown, it flows in cavities due to the roughness of the various layers, assembling the surfaces but not however affecting the electrical contacts.

We have just described a variant in which the layer of piezoelectric material is in contact with the dielectric film and the assembly is obtained by a thin layer of liquid adhesive.

According to another variant of the invention, it is also possible to use an intermediate adhesive conducting connection layer C₁. This intermediate conducting layer C1 may advantageously be anisotropic conducting material type, i.e. it has the property of being a conductor in a privileged direction and when hot pressed provides electrical contact only, for example, in a direction perpendicular to the plane of the dielectric film Fd, i.e. along a Z axis perpendicular to the (X, Y) plane shown on FIG. 4. This type of resin, whilst providing continuous, uniform adherence over a layer of piezoelectric material deposited on a substrate, only connects along a Z axis, not along X or Y axes, piezoelectric elements to electrical connections located on the dielectric film Fd. Typically, this material may include a binder loaded with conducting particles.

A layer C_{T} of piezoelectric material is then superposed on the intermediate conducting layer C₁.

Note that the layers C₁ and C_{T} do not cover the earth pads PM and the secondary connection pads Pcₛ which must be accessible from the side shown on FIGS. 2b and 4.

FIG. 5 illustrates a cross-section of a probe according to the invention comprising the layer C₁.

Generally, the acoustic impedance of the first layer Ca₁ is relatively high, and the layer Ca₂ represents an acoustic matching layer of lower acoustic impedance.

Typically, the layer Ca₁ may consist of a mixture of thermosetting or thermoplastic resin with metallic loads, type epoxy resin loaded with nickel. The volume resistivity of this type of material may typically be less than 10⁻³ Ω.m and its acoustic impedance approximately 9M Rayleigh, the layer Ca₂ advantageously has an impedance of approximately 3 Mega Rayleigh.

The thickness of the film Fₛ may advantageously lie between approximately 10 and 30 microns to allow correct draping (i.e. follow the shape of the layer of piezoelectric material: most often it is a PZT type ceramic blade of approximate thickness 150-600 μm) and to keep the flexibility of the earth pads. The dimensions of the probe can therefore be reduced by folding and gluing the earth pad on the sides of the absorber.

The assembly operations can be realized under vacuum or under pressure. Typically, either pressure is exerted above the draping film Fₛ, or a vacuum is produced underneath this film. The two effects can also be combined by creating a vacuum on the film Fₛ and enclosing the assembly in an envelope to which pressure is applied.

When the above-mentioned assembly operation(s) have been carried out, a cutting operation Tⱼ is then carried out to cut the assembly in order to separate the elementary piezoelectric transducers TPᵢ as shown on FIG. 6. This cutting operation can be carried out with a diamond saw in direction Dy as shown on FIG. 6. Linear transducers are thereby defined, of typical width between 50 and 500 microns. To electrically insulate the linear transducers, the cutting lines stop in the thickness of the dielectric film Fd.

The assembly previously produced can also be cut out by laser.

Lastly, the two types of cutting may be combined. The acoustic matching blades can therefore be cut by laser whereas the piezoelectric material, in this case the ceramic, can be cut using the mechanical saw. The latter cutting method releases the thermal stresses produced when bonding materials which have different thermal expansion coefficients. By cutting the acoustic matching blades first, the thermal stresses in the ceramic are released, so the ceramic does not break during the second cutting.

Once the linear transducers have been produced on the surface of the dielectric film, a traditional conformation operation can then be carried out, in order to realize curved probes, which are extremely useful in the field of ultrasonography.

Through the use of the flexible dielectric film and prior cutting of linear transducers, we obtain a sufficient degree of curvature of said dielectric film to assemble it on the surface of a curved absorber (material absorbing the sound waves). This assembly is carried out traditionally by bonding the flexible film on the surface of said absorber.

We have described the invention in the context of a unidirectional acoustic probe, but the invention may also be applied in the context of a probe with a connection network on the surface of the flexible dielectric film, in order to realize acoustic probes with matrix transducers, covered with linear acoustic matching elements.

In this case, the same method is used as when manufacturing unidirectional probes to deposit a layer of piezoelectric material via a flexible film Fₛ on a flexible dielectric film Fd (FIG. 2b).

A cutting operation is then carried out along an axis Dx to cut the piezoelectric material as illustrated on FIG. 7, which shows the cuts Tᵢ in the layer C_{T}. FIG. 8 illustrates a cross-section along axis BB′, after making the successive deposits of the film Fₛ/F_{c}, the layer C_{T} and the layers Ca₁ and Ca₂. Lastly, in the same way as for unidirectional probes with linear transducers, an operation to make cuts Tⱼ is carried out along the Y axis, to cut the assembly Ca₁/Ca₂/F_{c}/C_{T} down into the flexible dielectric film Fd.

FIG. 9 illustrates a cross-section along axis BB′ when using an intermediate conducting layer C₁. The cuts Tj along the Y axis are then made in the assembly Ca₁/Ca₂/F_{c}/C_{T}/C₁.

1. Method to manufacture acoustic probes with unitary piezoelectric transducers, wherein it comprises the following steps:
realization of a connection network comprising primary connections (Pcₚ) and earth pads (P_{M}), on the surface of a dielectric film (F_{d});
superposition of a layer of piezoelectric material (C_{T}) on the surface of the connection network;
realization of a conducting film (F_{c}) on the surface of a flexible film (Fₛ);
ablation over a specific area (S) of the flexible film (Fₛ), exposing the conducting film (F_{c}) over the area where the flexible film (Fₛ) has been removed;
assembly of the bared conducting film, on the surface of the piezoelectric material and of the flexible film on the surface of the dielectric film (F_{d});
an operation along a first axis (Dₓ) to cut (Tⱼ) the assembly consisting of the conducting film and the piezoelectric material (C_{T}) so as to define the unitary piezoelectric transducers (Tpᵢ).

2. Method to manufacture acoustic probes according to claim 1, wherein the conducting film (F_{c}) is a metallic film.

3. Method to manufacture acoustic probes according to claim 2, wherein it comprises the deposit of a first metallic layer (m₁) of a first thickness on the surface of the flexible film (Fs) followed by the deposit of a second metallic layer (m₂) of second thickness greater by at least one order of magnitude than the first thickness.

4. Method to manufacture acoustic probes according to claim 3, wherein the first metallic layer is realized by spraying a metal on the flexible film (Fₛ).

5. Method to manufacture acoustic probes according to claim 3 or 4, wherein the second metallic layer is realized by electrolytic deposit on the first metallic layer, of a metal identical to or different from that forming the first metallic layer.

6. Method to manufacture acoustic probes according to one of claims 2 to 5, wherein it comprises the deposit of a very thin layer of noble metal, for example gold, when producing the metallic film, to prevent oxidation of said metallic film.

7. Method to manufacture acoustic probes according to one of claims 2 to 6, wherein the metallic film is copper or nickel.

8. Method to manufacture acoustic probes according to one of claims 2 to 7, wherein the thickness of the conducting film is between approximately 5 and 10 microns.

9. Method to manufacture acoustic probes according to one of claims 1 to 8, wherein the ablation of the flexible film over a specific area, exposing the flexible film, is realized by a CO₂ laser.

10. Method to manufacture acoustic probes according to one of claims 1 to 9, wherein the assembly of the conducting film, on the surface of the piezoelectric material and of the flexible film on the surface of the dielectric film is realized with a liquid adhesive, the electrical contact between the various metallic surfaces being formed by the roughness of the surfaces

11. Manufacturing method according to one of claims 1 to 9, wherein it comprises the deposit of a conducting adhesive layer (C₁) on the surface of the dielectric film, to provide the electrical contact between the piezoelectric material (CT) and the primary connections Pcₚ).

12. Manufacturing method according to claim 11, wherein the conducting adhesive layer includes an anisotropic conducting material.

13. Method to manufacture acoustic probes according to one of claims 1 to 12, wherein it comprises in addition the deposit of at least an acoustic matching layer (Ca₁) on the surface of the conducting film (F_{c}) positioned on the piezoelectric material.

14. Method to manufacture acoustic probes according to claim 13, wherein it comprises the deposit of a first acoustic matching layer of high impedance (Ca₁) on the conducting film and the deposit of a second acoustic matching layer of low impedance (Ca₂), on the first acoustic matching layer.

15. Method to manufacture acoustic probes according to one of claims 1 to 14, wherein it comprises in addition a prior cutting operation (Tᵢ) along a second cutting axis (D_{y}) to cut the layer of the piezoelectric material in a direction perpendicular to the first cutting axis.
